(19) United States
(12) Patent Application Publication
(10) Pub. No.: US 2008/0020242 A1
(43) Pub. Date: Jan. 24, 2008

(54) Perpendicular magnetic recording medium and manufacturing method thereof

(75) Inventors: Hajime Kurihara, Minami-Alps City (JP); Tadaaki Oikawa, Kai City (JP); Kenichiro Soma, Minami-Alps City (JP)

Correspondence Address: ROSSI, KIMMS & McDOWELL LLP., P.O. BOX 826, ASHBURN, VA, 20146-0826, US

(73) Assignee: Fuji Electric Device Technology Co., Ltd., Tokyo (JP)

(21) Appl. No.: 11/685,452

(22) Filed: Mar. 13, 2007

(30) Foreign Application Priority Data
Jul. 20, 2006 (JP) 2006-198118

(51) Int. Cl. G11B 5/66; B05D 5/12; C23C 16/01

(52) U.S. Cl. 428/828.1; 264/81; 427/128; 427/132

(57) ABSTRACT

A perpendicular magnetic recording medium is disclosed. The formation of a domain wall in a soft magnetic backing layer relative to a large external magnetic field can be suppressed better in the medium, the Hk of the backing layer is improved, and productivity can be increased. The perpendicular magnetic recording medium is formed by laminating at least a soft magnetic backing layer, a non-magnetic underlayer, a magnetic recording layer, and a protective film in succession on a non-magnetic substrate. The backing layer, underlayer, magnetic recording layer, and protective film are formed by a vapor deposition method. The backing layer is a laminated body with a soft magnetic lower backing layer, non-magnetic metal layer, and soft magnetic upper backing layer. The non-magnetic metal layer is formed by forming a metal layer and then subjecting the metal layer to surface exposure processing using a nitrogen-containing gas containing 0.1 to 100 at % nitrogen.

### CROSS REFERENCE TO RELATED APPLICATIONS

This application claims priority from application Serial No. JP 2006-98118, filed on Jul. 20, 2006, the contents of which are incorporated herein by reference in their entirety.

### BACKGROUND OF THE INVENTION

A. Field of the Invention

The present invention relates to a perpendicular magnetic recording medium and a manufacturing method thereof. This magnetic recording medium is useful for installation in various types of magnetic recording apparatus.

B. Description of the Related Art

In recent years, perpendicular magnetic recording has gained attention over conventional longitudinal magnetic recording as a technique for increasing the density of magnetic recording.

A perpendicular magnetic recording medium has a magnetic recording layer formed from a hard magnetic material, and a backing layer containing a soft magnetic material which is used during recording onto the magnetic recording layer and serves to concentrate magnetic flux generated by a magnetic head. It is known that spike noise, which is one type of noise that causes problems in a perpendicular magnetic recording medium having the structure described above, is generated by a domain wall formed on the soft magnetic layer, i.e., the backing layer.

The mechanisms of domain wall formation and noise generation are as follows. When the soft magnetic layer is formed on a substrate, the anisotropy of the soft magnetic layer is small, and therefore a closure domain is generated in order to reduce the magnetostatic energy on the inner and outer peripheral portions of the soft magnetic layer. In a soft magnetic layer having an adequate film thickness for practical applications, the domain wall takes a Bloch form, and since spin rotates in the film thickness direction within the domain wall, perpendicular direction poles appear at the upper and lower ends of the domain wall, causing noise. In order to reduce noise in a perpendicular magnetic recording medium, the formation of a domain wall on the inner and outer peripheral portions of the soft magnetic layer must be prevented.

As regards control of the domain wall of the soft magnetic backing layer, when the magnetization directions of soft magnetic films forming the main part of a soft magnetic backing film are coupled anti-ferromagnetically so as to be oriented 180° from each other by providing a non-magnetic metal between the soft magnetic backing layers (see Japanese Unexamined Patent Application Publication H1-128226 and Japanese Unexamined Patent Application Publication H7-85442, for example), and when the substrate takes a disk shape, for example, the magnetization directions are aligned with the circumferential direction of the disk-shaped substrate. As a result, the generation of a domain wall that causes noise can be suppressed.

In a backing layer having the above structure, in which a non-magnetic metal is sandwiched between soft magnetic backing layers, the coupling force (exchange coupling magnetic field) that acts between the soft magnetic backing layers attenuates in a vibrating manner as the thickness of the non-magnetic metal film increases, while the non-magnetic metal film thickness at which a coupling force that produces anti-ferromagnetic coupling reaches a maximum depends on the electronic structure and crystalline orientation of the employed non-magnetic metal. Further, an anisotropic magnetic field Hk, which serves as a parameter for evaluating the characteristics of the soft magnetic backing layer, is determined by a saturation magnetization Ms and the film thickness of the soft magnetic material, the coupling force between the backing layers, or in other words the film thickness of the non-magnetic metal layer, and so on.

When providing a high quality perpendicular magnetic recording medium, a major problem is posed by a phenomenon of adjacent track erasure in which adjacent recording data on which writing has been performed become gradually smaller due to the effects of a return magnetic field from the soft magnetic backing layer, of the writing magnetic field of the head. To prevent adjacent track erasure, it is effective to increase the Hk of the soft magnetic backing layer.

The Hk value of the soft magnetic backing layer varies mainly in accordance with the values of the film thickness of the aforementioned non-magnetic metal layer, the Ms and film thickness of the soft magnetic material, and so on. Further, the Hk of the soft magnetic backing layer varies according to the formation process and layer configuration, and a method of forming anti-ferromagnetic thin films on the upper layer and lower layer of the soft magnetic backing layer and using exchange coupling to pin the magnetizations thereof, for example, has been proposed as a means for increasing the Hk from the structure surface. However, to obtain a sufficiently large Hk, complicated and expensive methods, such as performing heat treatment for several minutes to several hours following deposition or laminating together numerous soft magnetic layers and anti-ferromagnetic layers, must be employed, and therefore at present, many problems relating to productivity remain to be solved.

The present invention is directed to overcoming or at least reducing the effects of one or more of the problems set forth above.

### SUMMARY OF THE INVENTION

The present invention has been designed in consideration of the existence of these problems. It is an object of the invention, therefore, to provide a perpendicular magnetic recording medium and a manufacturing method thereof with which the formation of a domain wall in a soft magnetic backing layer relative to a large external magnetic field can be suppressed more favorably than in the related art, the Hk of the soft magnetic backing layer can be further improved, and productivity can be increased.

In a perpendicular magnetic recording medium of the present invention, which is formed by laminating at least a soft magnetic backing layer, a non-magnetic underlayer, a magnetic recording layer, and a protective film in succession on a non-magnetic substrate, the backing layer, underlayer, magnetic recording layer, and protective film are formed by a vapor deposition method. The backing layer is a laminated body comprising a soft magnetic lower backing layer, a non-magnetic metal layer, and a soft magnetic upper backing layer, and the non-magnetic metal layer is formed by forming a metal layer and then subjecting the metal layer to surface exposure processing using a nitrogen-containing gas containing 0.1 to 100 at % nitrogen.

A manufacturing method for a perpendicular magnetic recording medium of the present invention comprises a soft magnetic backing layer forming step in which a soft magnetic lower backing layer and a non-magnetic metal layer are formed in order on a non-magnetic substrate using a vapor deposition method, a surface of the formed non-magnetic metal layer is subjected to surface exposure processing using a nitrogen-containing gas containing 0.1 to 100 at % nitrogen, and then a soft magnetic upper backing layer is formed thereon using a vapor deposition method; a non-magnetic underlayer forming step for forming a non-magnetic underlayer on the formed soft magnetic backing layer using a vapor deposition method; a magnetic recording layer forming step for forming a magnetic recording layer on the formed non-magnetic underlayer using a vapor deposition method; and a protective film forming step for forming a protective film on the formed magnetic recording layer using a vapor deposition method.

According to the present invention, a perpendicular magnetic recording medium in which the Hk of the soft magnetic backing layer is high, and which is therefore effective in achieving further improvement in the recording and reproduction characteristics, can be obtained without the need for a special layer configuration. Further, according to the manufacturing method of the present invention, a high performance perpendicular magnetic recording medium can be manufactured with no accompanying cost increases, and hence this manufacturing method is highly suitable for mass production.

### BRIEF DESCRIPTION OF THE DRAWINGS

The foregoing advantages and features of the invention will become apparent upon reference to the following detailed description and the accompanying drawings, of which:

FIG. 1 is a sectional pattern diagram showing an embodiment of a perpendicular magnetic recording medium according to the present invention;

FIG. 2 is a view showing a hysteresis loop of a partial model body of a perpendicular magnetic recording medium obtained in a first comparative experimental example; and

FIG. 3 is a view showing a hysteresis loop of a partial model body of a perpendicular magnetic recording medium obtained in a first experimental example.

### DETAILED DESCRIPTION OF SPECIFIC EMBODIMENTS

The present invention will be described below with reference to the drawings.

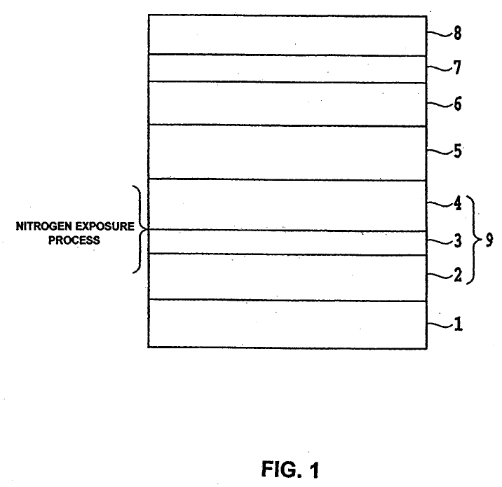

FIG. 1 is a sectional pattern diagram showing an embodiment of a perpendicular magnetic recording medium according to the present invention. The perpendicular magnetic recording medium of the present invention is structured such that at least soft magnetic backing layer 9, non-magnetic underlayer 5, magnetic recording layer 6, and protective film 7 are laminated in sequence on non-magnetic substrate 1. In the example shown in FIG. 1, liquid lubrication layer 8 is provided on protective film 7. Soft magnetic backing layer 9 is a laminated body comprising soft magnetic lower backing layer 2, non-magnetic metal layer 3, and soft magnetic upper backing layer 4. The non-magnetic metal layer 3 is formed by forming a metal layer and then subjecting the metal layer to surface exposure processing using a gas containing nitrogen.

Any substrate that is used in a typical magnetic recording medium may be employed as non-magnetic substrate 1 of the present invention, and specific examples thereof include an NiP-plated aluminum alloy substrate, a reinforced glass substrate, and a crystallized glass substrate.

Non-magnetic underlayer 5 used in the present invention is provided to control the crystalline orientation and grain size of magnetic recording layer 6, and Ru or an alloy containing Ru may be used as the metal of the non-magnetic underlayer.

A ferromagnetic material of an alloy containing at least Co and Cr is preferably used as magnetic recording layer 6 of the present invention. In the alloy, the c axis of the hexagonal close-packed structure is preferably oriented in a perpendicular direction to the film surface.

Protective film 7 may be formed from any material having the required mechanical strength, heat resistance, oxidation resistance, corrosion resistance, and so on, and when a conventionally used material is employed, there are no particular limitations on the material composition thereof. However, a thin film having carbon as a main constituent, for example, can be used favorably. A perfluoropolyether type lubricant, for example, may be used favorably as liquid lubrication layer 8.

A crystalline alloy such as an NiFe-based alloy, a sendust (FeSiAl) alloy, or a FeCo alloy having a large saturation magnetic flux density, or a non-crystalline Co alloy such as CoZrNb, CoTaZr, or the like, for example, may be used as soft magnetic lower backing layer 2 and soft magnetic upper backing layer 4 serving as constitutional elements of soft magnetic backing layer 9. The optimum film thickness values of soft magnetic lower backing layer 2 and soft magnetic upper backing layer 4 vary according to the structure and characteristics of the magnetic head used for recording, but in consideration of productivity, these values are each preferably set between 10 and 500 nm.

The easy magnetization axes of soft magnetic lower backing layer 2 and soft magnetic upper backing layer 4 must be coupled parallel to the substrate surface and oriented 180° from each other. The reason for this is that when the magnetizations of soft magnetic lower backing layer 2 and soft magnetic upper backing layer 4 sandwiching non-magnetic metal layer 3 are coupled in anti-parallel and anti-ferromagnetically, the orientation of the magnetizations does not vary even if an external magnetic field equal to or lower than the coupling strength thereof is applied. In other words, a domain wall is not generated in the soft magnetic layer, and the generation of spike noise can be suppressed.

A material having any metal of Cu, Ru, Rh, Pd, and Re or an alloy thereof as a main constituent may be used as non-magnetic metal layer 3. The film thickness of non-magnetic metal layer 3 must be selected appropriately such that the easy magnetization axes of soft magnetic lower layer 2 and soft magnetic upper backing layer 4 are oriented parallel to the substrate surface and in 180° opposing directions, and such that a powerful coupling strength is obtained. To obtain a high level of resistance to an external magnetic field, however, the film thickness of non-magnetic metal layer 3 is preferably set between 0.1 and 5 nm. The reason for this is as follows.

As the film thickness of non-magnetic metal layer 3 increases gradually from 0 nm, a coupling whereby the easy magnetization axes of soft magnetic lower backing layer 2 and soft magnetic upper backing layer 4 are parallel to the substrate and oriented in the same direction (ferromagnetic coupling) and a coupling whereby the easy magnetization axes are parallel to the substrate surface and oriented in 180° opposing directions (anti-ferromagnetic coupling) appear alternately. For example, when Ru is used as non-magnetic metal layer 3, soft magnetic lower backing layer 2 and soft magnetic upper backing layer 4 are coupled ferromagnetically within an Ru film thickness range of 0 to 0.3 nm, and are coupled anti-ferromagnetically within a range of 0.3 to 1.2 nm. When the film thickness is increased further, soft magnetic lower backing layer 2 and soft magnetic upper backing layer 4 are coupled ferromagnetically within a range of 1.2 to 1.8 nm, and coupled anti-ferromagnetically within a range of 1.8 to 3.0 nm.

The film thickness ranges in which ferromagnetic coupling is achieved and the film thickness ranges in which anti-ferromagnetic coupling is achieved differ according to the metal in use, and therefore, in consideration of cases employing various different metals, the film thickness for exhibiting anti-ferromagnetic coupling is preferably set at no less than 0.1 nm.

The coupling strength of soft magnetic lower backing layer 2 and soft magnetic upper backing layer 4 decreases as the film thickness of non-magnetic metal layer 3 increases. As the coupling strength increases, the resistance to an external magnetic field increases, and although this characteristic varies according to the type of metal used for non-magnetic metal layer 3, the film thickness of non-magnetic metal layer 3 is preferably set at no more than 5 nm in order to secure sufficient resistance to a floating magnetic field in a hard disk drive.

Non-magnetic metal layer 3 is subjected to surface exposure processing using a nitrogen-containing gas containing 0.1 to 100 at % nitrogen. When soft magnetic backing layer 9 has a non-magnetic metal layer whose surface has been subjected to surface exposure processing using a nitrogen-containing gas containing 0.1 to 100 at % nitrogen between soft magnetic lower backing layer 2 and soft magnetic upper backing layer 4, an improvement in the anisotropic magnetic field Hk of approximately 200 Oe to 300 Oe can be seen in comparison with the Hk value of a soft magnetic backing layer having a non-magnetic metal layer that has not been subjected to this surface processing between soft magnetic lower backing layer 2 and soft magnetic upper backing layer 4. When the nitrogen concentration of the nitrogen-containing gas is less than 0.1 at %, the improvement in Hk is insufficient. An inert gas such as Ar may be used as a gas component other than nitrogen when the nitrogen-containing gas is not 100 at % nitrogen. When the nitrogen-containing gas contains oxygen in addition to nitrogen and an inert gas, the Hk improving effect of the nitrogen is not inhibited significantly provided the amount of oxygen is less than 2 at %, and therefore the nitrogen-containing gas may contain oxygen.

The processing time of the surface exposure processing using the nitrogen-containing gas is preferably set between 0.1 and 10 seconds. Below 0.1 seconds, the surface exposure processing effect is insufficient, and above 10 seconds, no further improvements in the processing effect are obtained, and the cost of the gas used increases. Furthermore, the atmosphere of the surface exposure processing is preferably set in a pressure range of 3 to 120 mTorr.

The backing layer, underlayer, magnetic recording layer, and protective film are formed by a vapor deposition method. Examples of vapor deposition methods include physical vapor deposition and chemical vapor deposition (CVD), and examples of physical vapor deposition methods include sputtering and vacuum deposition. In other words, sputtering, vacuum deposition, and CVD may be cited as vapor deposition methods. DC (direct current) magnetron sputtering and RF (radio frequency) magnetron sputtering may be cited as sputtering methods.

When a plurality of layers are to be formed using vapor deposition, all of the layers may be formed by the same vapor deposition method, or a different vapor deposition method may be selected for each layer to be formed. In other words, any of sputtering, vacuum deposition, and CVD, or a combination of two or more thereof, may be employed as the vapor deposition method.

Next, a manufacturing method of the perpendicular magnetic recording medium according to the present invention will be described.

First, the manufacturing method of the present invention comprises a process for forming soft magnetic backing layer 9, in which soft magnetic lower backing layer 2 and non-magnetic metal layer 3 are formed in order on non-magnetic substrate 1 using a vapor deposition method, the surface of the formed non-magnetic metal layer 3 is subjected to surface exposure processing using a nitrogen-containing gas containing 0.1 to 100 at % nitrogen, and soft magnetic upper backing layer 4 is then formed on non-magnetic metal layer 3 using a vapor deposition method. The materials used for forming non-magnetic substrate 1, soft magnetic lower backing layer 2, non-magnetic metal layer 3, and soft magnetic upper backing layer 4 are as noted above in the description of the perpendicular magnetic recording medium.

In this manufacturing method, the film thickness of the soft magnetic lower backing layer is preferably between 10 and 500 nm, the film thickness of the non-magnetic metal layer is preferably between 0.1 and 5 nm, and the film thickness of the soft magnetic upper backing layer is preferably between 10 and 500 nm. The reasons for this are as noted above in the description of the perpendicular magnetic recording medium.

Further, the manufacturing method of the present invention comprises a process for forming non-magnetic underlayer 5 on soft magnetic backing layer 9 formed in the manner described above using a vapor deposition method. The materials used for forming non-magnetic underlayer 5 are as noted above in the description of the perpendicular magnetic recording medium.

The manufacturing method of the present invention further comprises a process for forming magnetic recording layer 6 on non-magnetic underlayer 5 formed in the manner described above using a vapor deposition method. The materials used for forming magnetic recording layer 6 are as noted above in the description of the perpendicular magnetic recording medium. The manufacturing method of the present invention further comprises a process for forming protective film 7 on magnetic recording layer 6 formed in the manner described above using a vapor deposition method. The vapor deposition methods employed in the manufacturing method of the present invention are as noted above in the description of the perpendicular magnetic recording medium.

The manufacturing method of the present invention may include a process for providing liquid lubricant layer 8 on protective film 7 formed in the manner described above. The aforementioned lubricant may be used as a lubricant, and a dip-coat method or spin coat method, for example, may be employed to form the liquid lubricant layer.

### EXAMPLES

The perpendicular magnetic recording medium and manufacturing method thereof according to the present invention will be described in further detail below using experimental examples.

### First Experimental Example

A chemically strengthened glass substrate having a smooth surface (N-5 glass substrate, manufactured by HOYA) was used as non-magnetic substrate 1. After being washed, the substrate was introduced into a sputtering apparatus, and using a Co85Zr10Nb5 target, CoZrNb amorphous soft magnetic lower backing layer 2 was deposited at 110 nm using a DC magnetron sputtering method. Next, using a Ru target, Ru non-magnetic metal layer 3 was deposited at 0.8 nm using a DC magnetron sputtering method.

Next, using Ar gas containing 10 at % nitrogen gas (Ar-10% N₂ gas), the surface of Ru non-magnetic metal layer 3 was subjected to nitrogen exposure processing for 3 seconds in an atmosphere of 10 mTorr. Then, again using a Co85Zr10Nb5 target, CoZrNb amorphous soft magnetic upper backing layer 4 was deposited at 90 nm using a DC magnetron sputtering method. Next, using a carbon target, protective film 7 made of carbon was deposited at 10 nm using a DC magnetron sputtering method, whereupon the structure was removed from the sputtering apparatus. Next, 2 nm thick liquid lubrication layer 8 of perfluoropolyether was formed using a dip-coat method, and thus a partial model body of a disk-shaped perpendicular magnetic recording medium having neither a non-magnetic underlayer nor a magnetic recording layer was created.

Note that the film thickness of the non-magnetic metal layer was selected such that the Hk value of the soft magnetic backing layer reached a maximum, and to verify the increase or decrease in Hk according to the application of the nitrogen exposure process, the film thickness of the non-magnetic metal layer was made identical in each experimental example, including a comparative experimental example.

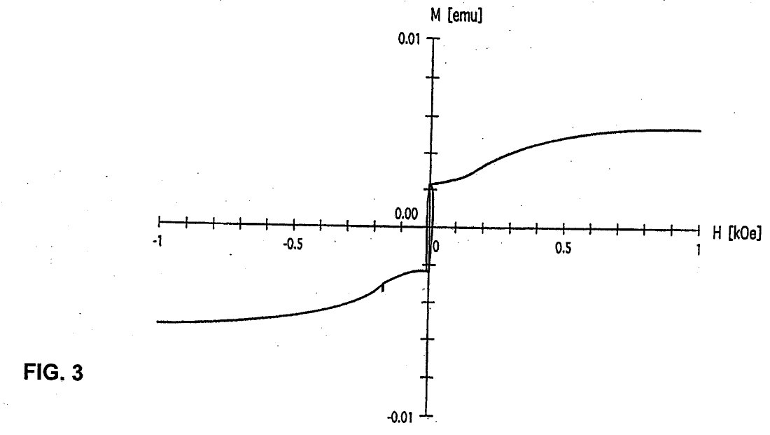

FIG. 3 shows the results obtained when a hysteresis loop of the obtained medium in a hard magnetization axis direction (radial direction) was measured using a vibration sample magnetometer (VSM). In the hard axis direction hysteresis loop, the Hk value of the soft magnetic backing layer is determined as the value (Oe) of the applied magnetic field when magnetization is saturated. The Hk value of the perpendicular magnetic recording medium according to the first experimental example was determined to be 754 Oe.

### Second Experimental Example

In the nitrogen exposure process, exposure was performed for 10 seconds using Ar-0.1% N₂ gas. Otherwise, a partial model body of a disk-shaped perpendicular magnetic recording medium having neither a non-magnetic underlayer nor a magnetic recording layer was created in a similar manner to the first experimental example. The Hk value was determined in a similar manner to the first experimental example using the obtained medium. The results are shown in Table 1 together with the results of the first experimental example.

### Third Experimental Example

Pure N₂ (100%) gas was used in the nitrogen exposure process. Otherwise, a partial model body of a disk-shaped perpendicular magnetic recording medium having neither a non-magnetic underlayer nor a magnetic recording layer was created in a similar manner to the first experimental example. The Hk value was determined in a similar manner to the first experimental example using the obtained medium. The results are shown in Table 1 together with the results of the first experimental example.

### Fourth Experimental Example

In the nitrogen exposure process, Ar-10% N₂-2% O₂ gas with added oxygen was used. Otherwise, a partial model body of a disk-shaped perpendicular magnetic recording medium having neither a non-magnetic underlayer nor a magnetic recording layer was created in a similar manner to the first experimental example. The Hk value was determined in a similar manner to the first experimental example using the obtained medium. The results are shown in Table 1 together with the results of the first experimental example.

### First Comparative Experimental Example

A nitrogen exposure process was not performed. Otherwise, a partial model body of a disk-shaped perpendicular magnetic recording medium having neither a non-magnetic underlayer nor a magnetic recording layer was created in a similar manner to the first experimental example.

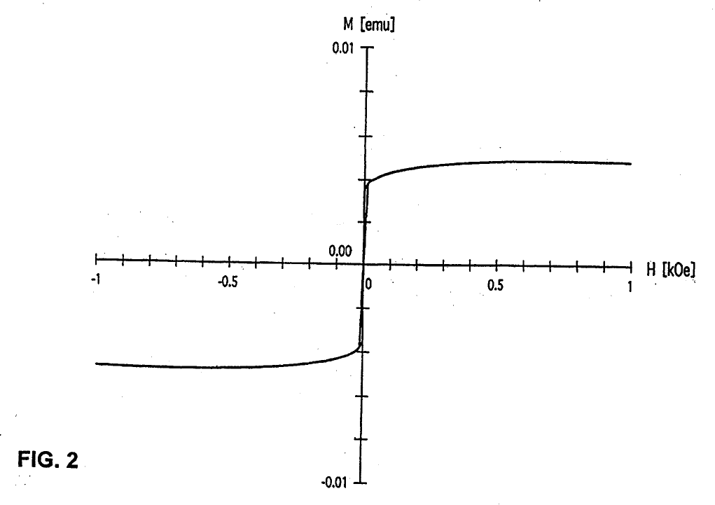

FIG. 2 shows the results obtained when a hysteresis loop of the obtained medium in the hard magnetization axis direction (radial direction) was measured using a vibration sample magnetometer (VSM). The Hk value of the perpendicular magnetic recording medium of the first comparative experimental example was determined to be 398 Oe.

### First Example

Similarly to the first experimental example, CoZrNb amorphous soft magnetic lower backing layer 2 and Ru non-magnetic metal layer 3 were laminated onto non-magnetic substrate 1 constituted by a chemically strengthened glass substrate (N-5 glass substrate, manufactured by HOYA), and the surface of Ru non-magnetic metal layer 3 was subjected to nitrogen exposure processing, whereupon CoZrNb amorphous soft magnetic upper backing layer 4 was deposited. Ta was then deposited at a thickness of 6 nm on soft magnetic backing layer 9 obtained in this manner in a sputtering apparatus using a DC magnetron sputtering method to form non-magnetic underlayer 5, and Co77Cr9Pt10SiO₂4 was deposited thereon at 20 nm as magnetic recording layer 6. Next, similarly to the first experimental example, carbon protective film 7 was formed on magnetic recording layer 6, whereupon liquid lubrication layer 8 was formed from perfluoropolyether, and thus the disk-shaped perpendicular magnetic recording medium was obtained. The SN ratio of the obtained perpendicular magnetic recording medium is shown in Table 1.

### Second to Fourth Examples, First Comparative Example

The perpendicular magnetic recording media of the second to fourth examples and the first comparative example were obtained in a similar manner to the first example except that the second to fourth experimental examples and the first comparative experimental example were followed instead of the first experimental example. The SN ratios of the obtained perpendicular magnetic recording media are shown in Table 1.

TABLE 1

| | | | | ANISOTROPIC | |
|---|---|---|---|---|---|
| | | | EXPOSURE | MAGNETIC | |
| | N₂ CONC | O₂ CONC | TIME | FIELD | SN RATIO |
| | (at %) | (at %) | (seconds) | (Oe) | (dB) |
| FIRST | 10 | — | 3 | 754 | 15.2 |
| EXPERIMENTAL | | | | | |
| EXAMPLE | | | | | |
| SECOND | 0.1 | — | 10 | 688 | 14.9 |
| EXPERIMENTAL | | | | | |
| EXAMPLE | | | | | |
| THIRD | 100 | — | 3 | 791 | 15.4 |
| EXPERIMENTAL | | | | | |
| EXAMPLE | | | | | |
| FOURTH | 10 | 2 | 3 | 703 | 15.1 |
| EXPERIMENTAL | | | | | |
| EXAMPLE | | | | | |
| FIRST | — | — | — | 398 | 14.3 |
| COMPARATIVE | | | | | |
| EXPERIMENTAL | | | | | |
| EXAMPLE | | | | | |

It can be seen from a comparison of the first experimental example and the comparative experimental example that by performing the nitrogen exposure process, an improvement in Hk of approximately 1.9 times is obtained. In other words, the Hk can be increased using a simple method merely involving nitrogen exposure processing, without the need for complicated and expensive methods.

Further, it can be seen from Table 1 that as the nitrogen concentration of the exposure processing gas for exposing the surface of the non-magnetic metal increases, the Hk of the soft magnetic backing layer improves. For example, the Hk of the perpendicular magnetic recording medium of the third experimental example, in which exposure processing is performed using 100% nitrogen gas, is 791 Oe, which is approximately twice that of the comparative experimental example and the highest value in Table 1. Note that no differences in Hk were found within a nitrogen-containing gas exposure processing time range of 0.1 to 10 seconds. Further, it is evident from the fourth experimental example that even when the nitrogen-containing gas used for exposure processing contains oxygen, a nitrogen-induced Hk improving effect can be exhibited.

It also was found from the first to fourth examples and the first comparative example that as the Hk value of the soft magnetic backing layer increases, a steadily more favorable SN ratio is obtained. For example, in comparison with the first comparative example, in which nitrogen exposure is not performed, the third example, in which 100% nitrogen gas is used, exhibits an improvement of approximately 1.0 dB in the SN ratio.

According to the present invention, an increase in Hk can be achieved using a simple process of subjecting the surface of the non-magnetic metal layer to nitrogen gas exposure, without the need for a special layer configuration, and therefore the present invention incurs substantially no cost increases, is suitable for mass production, and is useful as means for improving the SN ratio of a perpendicular magnetic recording medium.

Thus, a perpendicular magnetic recording medium and manufacturing method thereof has been described according to the present invention. Many modifications and variations may be made to the techniques and structures described and illustrated herein without departing from the spirit and scope of the invention. Accordingly, it should be understood that the media and methods described herein are illustrative only and are not limiting upon the scope of the invention.

What is claimed is:

1. A perpendicular magnetic recording medium comprising, in order:
a non-magnetic substrate;
a vapor-deposited soft magnetic backing layer comprising a soft magnetic lower backing layer, a surface-treated non-magnetic metal layer, and a soft magnetic upper backing layer, wherein said surface-treated non-magnetic metal layer has been exposed on its surface to a nitrogen-containing gas containing 0.1 to 100 at % nitrogen prior to deposition of said soft magnetic upper backing layer;
a vapor-deposited magnetic recording layer; and
a vapor-deposited protective film.

2. The perpendicular magnetic recording medium according to claim 1, wherein a film thickness of said soft magnetic lower backing layer is between 10 and 500 nm, a film thickness of said non-magnetic metal layer is between 0.1 and 5 nm, and a film thickness of said soft magnetic upper backing layer is between 10 and 500 nm.

3. The perpendicular magnetic recording medium according to claim 2, wherein said non-magnetic metal layer is formed from a material having any metal of Cu, Ru, Rh, Pd, and Re, or an alloy thereof, as a main constituent.

4. A perpendicular magnetic recording medium formed by laminating at least a soft magnetic backing layer, a non-magnetic underlayer, a magnetic recording layer, and a protective film in succession on a non-magnetic substrate,
wherein said backing layer, said underlayer, said magnetic recording layer, and said protective film are formed by a vapor deposition method,
said backing layer is a laminated body comprising a soft magnetic lower backing layer, a non-magnetic metal layer, and a soft magnetic upper backing layer, and
said non-magnetic metal layer is formed by forming a metal layer and then subjecting said metal layer to surface exposure processing using a nitrogen-containing gas containing 0.1 to 100 at % nitrogen.

5. The perpendicular magnetic recording medium according to claim 4, wherein said vapor deposition method is any one of a sputtering method, a vacuum deposition method, and a CVD method, or a combination of two or more thereof.

6. The perpendicular magnetic recording medium according to claim 4, wherein a film thickness of said soft magnetic lower backing layer is between 10 and 500 nm, a film thickness of said non-magnetic metal layer is between 0.1 and 5 nm, and a film thickness of said soft magnetic upper backing layer is between 10 and 500 nm.

7. The perpendicular magnetic recording medium according to claim 4, wherein said non-magnetic metal layer is formed from a material having any metal of Cu, Ru, Rh, Pd, and Re, or an alloy thereof, as a main constituent.

8. A manufacturing method for a perpendicular magnetic recording medium, comprising:
forming a soft magnetic backing layer comprising by forming a soft magnetic lower backing layer and a non-magnetic metal layer in order on a non-magnetic substrate using a vapor deposition method, subjecting a surface of the non-magnetic metal layer to surface exposure processing using a nitrogen-containing gas containing 0.1 to 100 at % nitrogen, and then forming a soft magnetic upper backing layer on the non-magnetic metal layer using a vapor deposition method;
forming a non-magnetic underlayer on the soft magnetic backing layer using a vapor deposition method;
forming a magnetic recording layer on the non-magnetic underlayer using a vapor deposition method; and
forming a protective film on the magnetic recording layer using a vapor deposition method.

9. The manufacturing method for a perpendicular magnetic recording medium according to claim 8, wherein the vapor deposition method is selected from the group consisting of a sputtering method, a vacuum deposition method, a CVD method, and a combination of two or more of these methods.

10. The manufacturing method for a perpendicular magnetic recording medium according to claim 8, wherein a film thickness of said soft magnetic lower backing layer is between 10 and 500 nm, a film thickness of said non-magnetic metal layer is between 0.1 an5 nm, and a film thickness of said soft magnetic upper backing layer is between 10 and 500 nm.

11. The manufacturing method for a perpendicular magnetic recording medium according to claim 8, wherein said non-magnetic metal layer is formed from a material having any metal of Cu, Ru, Rh, Pd, and Re, or an alloy thereof, as a main constituent.
